(19) United States
(12) Patent Application Publication
(10) Pub. No.: US 2009/0050885 A1
(43) Pub. Date: Feb. 26, 2009

(54) Semiconductor wafers and methods of fabricating semiconductor devices

(75) Inventors: Yun-rae Cho, Seoul (KR); Young-min Lee, Asan-si (KR); Min-keun Kwak, Cheonan-si (KR); Shin Kim, Cheonan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/222,350

(22) Filed: Aug. 7, 2008

(30) Foreign Application Priority Data
Aug. 8, 2007 (KR) 10-2007-0079780

(51) Int. Cl. H01L 23/58; H01L 21/66

(52) U.S. Cl. 257/48; 438/14

(57) ABSTRACT

A semiconductor wafer includes a plurality of unitary semiconductor chips formed on a semiconductor substrate. Scribe lane region separate the unitary semiconductor chips from each other. Test element group (TEG) pads are configured to apply testing signals for testing respective test elements. A TEG pad is arranged such that an acute angle formed at an intersection of a line extending from portion of a perimeter of the TEG pad and at least a portion of the outer edge of a corresponding scribe lane region is greater than 0° and less than or equal to 60°.

### PRIORITY STATEMENT

This application priority under 35 U.S.C. § 119 to Korean Patent Application No. 10-2007-0079780, filed on Aug. 8, 2007, in the Korean Intellectual Property Office, the entire contents of which is incorporated herein by reference.

### BACKGROUND

### Description of the Related Art

A relatively large number of unitary semiconductor chips may be disposed on a semiconductor wafer. The unitary semiconductor chips are separated from each other by scribe lanes or scribe lane regions. Test elements for testing semiconductor devices formed on the unitary semiconductor chips are disposed in the scribe lanes. Tested semiconductor devices include, for example, individual transistor devices respectively formed on the unitary semiconductor chips. Also formed on the scribe lines are test element group (TEG) pads. The TEG pads apply testing signals to test the test elements.

A conventional TEG pad is formed as shown in FIG. 1. When the conventional TEG pad is diced using a dicing blade, a burr as shown in FIG. 2A may be formed, or peeling as shown in FIGS. 2B and 2C may occur. The burr and/or peeling may contact elements such as wire bonds during a subsequent packaging operation, which may cause the entire semiconductor device to fail.

### SUMMARY

Example embodiments relate to semiconductor wafers and methods of manufacturing semiconductor devices, for example, to semiconductor wafers and methods of manufacturing semiconductor devices suppressing and/or preventing formation of a burr and/or the occurrence of peeling in a dicing operation.

At least one example embodiment provides semiconductor wafers in which the formation of a burr and/or the occurrence of peeling when dicing the semiconductor wafers may be reduced (e.g., significantly reduced).

At least one other example embodiment provides methods of fabricating semiconductor devices in which the formation of the burr and/or the occurrence of peeling when dicing the semiconductor wafer may be reduced (e.g., significantly reduced).

Example embodiments also provide electronic devices including a semiconductor device.

At least one example embodiment provides a semiconductor wafer including a plurality of unitary semiconductor chips formed on a semiconductor substrate. A scribe lane region may separate the unitary semiconductor chips from each other. Test elements may be formed on scribe lanes within the scribe lane region. Test element group (TEG) pads may be configured to apply testing signals for testing the test elements, respectively. An acute angle formed at an intersection at which an extended line of at least a portion of the perimeter of the TEG pads and at least a portion of the outer edge of the scribe lanes cross is greater than 0° and less than or equal to 60°. According to at least one example embodiment, the acute angle may be between about 10° and about 50°, inclusive.

At least one other example embodiment provides a semiconductor wafer including a plurality of unitary semiconductor chips formed on a semiconductor substrate and a scribe lane region separating the plurality of unitary semiconductor chips from each other. Test element group (TEG) pads may be arranged within the scribe lane regions. The TEG pads may be configured to apply testing signals for testing respective test elements. At least a first of the TEG pads may be arranged such that an acute angle formed at an intersection of a line extending from portion of a perimeter of the first TEG pad and at least a portion of the outer edge of a scribe lane region is greater than 0° and less than or equal to 60°.

At least one other example embodiment provides a semiconductor wafer including a plurality of unitary semiconductor chips formed on a semiconductor substrate and a scribe lane region separating the plurality of unitary semiconductor chips from each other. Test element group (TEG) pads may be arranged within the scribe lane regions. The TEG pads may be configured to apply testing signals for testing respective test elements. At least a first of the TEG pads may be arranged such that an acute angle formed at an intersection of at least a portion of a perimeter of the first TEG pad and a cutting line to be formed by dicing the semiconductor wafer in a direction in which the scribe lane region extends is greater than 0° and less than or equal to 60°.

According to at least some example embodiments, a length in which one of the TEG pads overlaps a cutting line may be smaller than about 40 μm, for example, smaller than about 25 μm. Selectively, the TEG pad may have a substantially rectangular shape, and an acute angle formed at an intersection at which one or more of two neighboring sides of the rectangle and the cutting line cross may be greater than 0° and less than or equal to 60°. The TEG pad may have a substantially square shape. Alternatively, the TEG pad may have either circular or elliptical shape.

At least one other example embodiment provides a method of fabricating a semiconductor device. According to at least this example embodiment, unitary semiconductor chip regions may be formed on a semiconductor substrate. Scribe lane regions may be formed between the unitary semiconductor chip regions. Test elements may be formed on the scribe lane regions; and TEG pads configured apply a testing signal for testing the test elements may be formed. An acute angle formed at an intersection at which an extended line of at least a portion of the perimeter of the TEG pads and at least a portion of the outer edge of the scribe lanes or scribe lane regions cross may be greater than 0° and less than or equal to 60°.

At least one other example embodiment provides a method of fabricating a semiconductor device. According to at least this example embodiment, unitary semiconductor chip regions may be formed on a semiconductor substrate. Scribe lane regions may be formed between the unitary semiconductor chip regions. Test element group (TEG) pads may be formed in the scribe lane regions. The TEG pads may be configured to apply a testing signal for testing respective test elements. At least a first of the TEG pads may be arranged such that an acute angle formed at an intersection of a line extending from portion of a perimeter of the first TEG pad and at least a portion of the outer edge of a scribe lane region is greater than 0° and less than or equal to 60°.

According to at least one example embodiment, the acute angle may be between about 10° and about 50°, inclusive. A length in which one of the TEG pads overlaps a cutting line may be smaller than about 40 μm, for example, smaller than about 25 μm. Selectively, the TEG pad may have a substantially rectangular shape, and an acute angle formed at an intersection at which one or more of two neighboring lines of the rectangle and the cutting line may be greater than 0° and less than or equal to 60°. The TEG pad may have a substantially square shape. Alternatively, the TEG pad may have either circular or elliptical shape.

At least one other example embodiment provides an electronic device including the unitary semiconductor chip formed on a semiconductor wafer. In one example, the semiconductor wafer may include a plurality of unitary semiconductor chips formed on a semiconductor substrate and a scribe lane region separating the plurality of unitary semiconductor chips from each other. Test element group (TEG) pads may be arranged within the scribe lane regions. The TEG pads may be configured to apply testing signals for testing respective test elements. At least a first of the TEG pads may be arranged such that an acute angle formed at an intersection of a line extending from portion of a perimeter of the first TEG pad and at least a portion of the outer edge of a scribe lane region is greater than 0° and less than or equal to 60°.

According to example embodiments, formation of a burr and/or a peeling in dicing a semiconductor wafer may be reduced (e.g., significantly reduced).

### BRIEF DESCRIPTION OF THE DRAWINGS

The present invention will become more apparent by describing in detail example embodiments thereof with reference to the attached drawings in which:

FIG. 1 is a picture of a conventional test element group (TEG) pad;

FIG. 2A is a picture of a burr formed by dicing the conventional TEG pad of FIG. 1;

FIGS. 2B and 2C are pictures of peeling formed by dicing the conventional TEG pad of FIG. 1;

FIG. 3 is a top view and a partially magnified view of a semiconductor wafer according to an example embodiment;

FIG. 4 is a detailed diagram for describing a scribe lane region of the semiconductor wafer of FIG. 3; and

FIG. 5 is a cross-sectional view of the scribe lane region of FIG. 3 obtained along a line V-V′ of FIG. 4.

### DETAILED DESCRIPTION OF EXAMPLE EMBODIMENTS

Various example embodiments of the present invention will now be described more fully with reference to the accompanying drawings in which some example embodiments of the invention are shown. In the drawings, the thicknesses of layers and regions are exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

Further, it will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

Further still, it will be understood that when an element or layer is referred to as being “formed on,” another element or layer, it can be directly or indirectly formed on the other element or layer. That is, for example, intervening elements or layers may be present. In contrast, when an element or layer is referred to as being “directly formed on,” to another element, there are no intervening elements or layers present. Other words used to describe the relationship between elements or layers should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

At least one example embodiment provides a semiconductor wafer including a plurality of unitary semiconductor chips formed on a semiconductor substrate. The semiconductor wafer further includes a scribe lane region separating the unitary semiconductor chips from each other. Test elements and a test element group (TEG) pad may be arranged on the scribe lane region. The test element group (TEG) pad may apply a testing signal for testing the test element. An acute angle formed at an intersection of the extended line of at least a portion of a perimeter of the TEG pad and at least a portion of the outer edge of the scribe lane and/or scribe lane region may be greater than 0° and less than or equal to 60°.

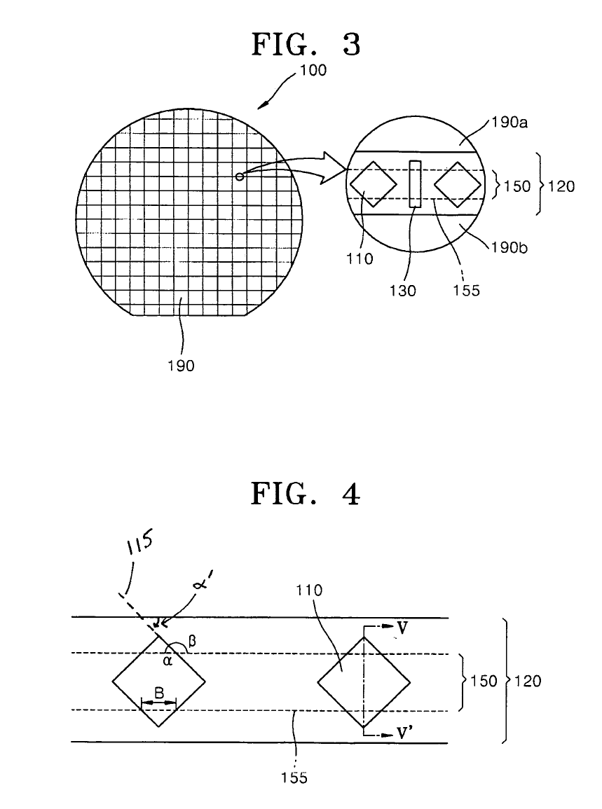

FIG. 3 is a top view and a partially magnified view of a semiconductor wafer 100 according to an example embodiment.

Referring to FIG. 3, the semiconductor wafer 100 may include a plurality of unitary semiconductor chips 190 (190a and 190b in the magnified view portion of FIG. 3) and a scribe lane region 120 separating the unitary semiconductor chips 190 from each other. A test element 130 and a TEG pad 110 may be formed in the scribe lane region 120. The TEG pad 110 and the test element 130 may be electrically connected to each other such that the TEG pad 110 may apply a testing signal for testing the test element 130.

Generally, the unitary semiconductor chips 190 are separated from each other by dicing the semiconductor wafer 100 along the boundary of the scribe lane region 120. As a result of the dicing, a cutting section 150 may be formed within a cutting line 155 (shown as a dash line at the boundary of the cutting section 150). The width of the cutting section 150 is also referred to as the Kerf width. The Kerf width must be smaller than the width of the scribe lane region 120.

FIG. 4 is a diagram for describing the scribe lane region 120 shown in FIG. 3 in more detail. For the sake of clarity, the test element 130 is omitted from FIG. 4.

Referring to FIG. 4, the TEG pad 110 may cross the cutting line 155. While the size of the TEG pad 110 may be made small enough to fit within the cutting lines 155, reducing the size of the TEG pad 110 may result increased costs associated with a probe card required for testing the test element 130.

Example embodiments show that the formation of a burr and/or the occurrence of peeling may be reduced (e.g., significantly reduced) by adjusting an angle α′ of an intersection at which the extended line 115 of at least a portion of the perimeter of the TEG pad 110 and the outer edge of the scribe lane region 120 cross. An acute angle α′ of the intersection between the extended line 115 and an outer edge of the scribe lane region 120 may be greater than 0° and less than or equal to 60°. In a more specific example, the acute angle α′ may be between about 10° and about 50°, inclusive. The extended line 115 is illustrate in FIG. 4 for the sake of clarity, but is omitted from the actual semiconductor wafer 100.

In another example, the formation of the burr and/or the occurrence of peeling may be reduced (e.g., significantly reduced) by adjusting an acute angle α, from among the two angles α and β formed at an intersection, to be greater than 0° and less than or equal to 60°. The acute angle α is the acute angle between a portion of the perimeter of the TEG pad 110 and a cutting line 155. In a more specific example, the acute angle α may be between about 10° and about 50°, inclusive. Selectively, an acute angle formed at an intersection at which at least a portion of the perimeters of at least a portion of the TEG pads and a cutting line to be formed by dicing the semiconductor wafer 100 in a direction in which the scribe lane region 120 extends may be greater than 0° and less than or equal to 60°.

The shape of the TEG pad 110 may be that of a square (as shown in FIG. 4), a rectangle, a rhombus, a circle, an ellipse or a similar shape. In a case where the TEG pad 110 has a circular, substantially circular, elliptical or substantially elliptical shape having a curved perimeter, the acute angle α may be an angle formed at an intersection at which the cutting line 155 crosses with a line tangent to the curved perimeter of the TEG pad 110 having a circular, substantially circular, elliptical or substantially elliptical shape.

Selectively, the TEG pad 110 may have a substantially rectangular shape, and an acute angle formed at an intersection at which at least one of two neighboring sides of the rectangle and the cutting line 155 cross may be greater than 0° and less than or equal to 60°. Alternatively, the rectangle may be a square.

Accordingly, not only an acute angle α formed at an intersection at which the perimeter of the TEG pad 110 and the cutting line 155 cross, but also an overlapping length B (refer to FIG. 4) may also affect the formation of a burr and/or the occurrence of peeling. The length B may be a length for which the TEG pad 110 and the cutting line 155 overlap (e.g., significantly). The overlapping length B may be less than about 40 μm, for example, less than about 25 μm.

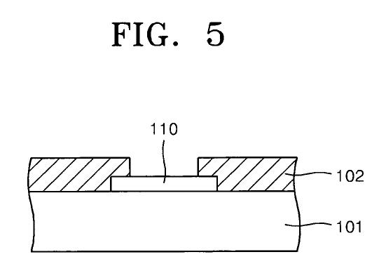

FIG. 5 is a cross-sectional view of the scribe lane region 120 of FIG. 4, obtained along a line V-V′ of FIG. 4. As shown in FIG. 5, the TEG pad 110 may be formed on a semiconductor substrate 101 such that the end of the TEG pad 110 is at least partially overlapped by (e.g., inserted into) an insulation layer 102. The insulation layer 102 may be, for example, an oxide layer or the like. The insulation layer 102 may have at least some effect of suppressing and/or preventing formation of a burr and/or the occurrence of peeling when the TEG pad 110 adjacent to the insulation layer 102 is diced. Therefore, when the perimeter of the TEG pad 110 crosses the cutting line 155 in the acute angle α (as shown in FIGS. 3 and 4) a region, which the formation of a burr and/or the occurrence of peeling may be suppressed and/or prevented, formed in the TEG pad 110 may be wider and more extensive than that of the conventional art in which the region is formed vertically. As a result, the formation of a burr and/or the occurrence of peeling may be suppressed and/or prevented more significantly in accordance with example embodiment, as opposed to the conventional art.

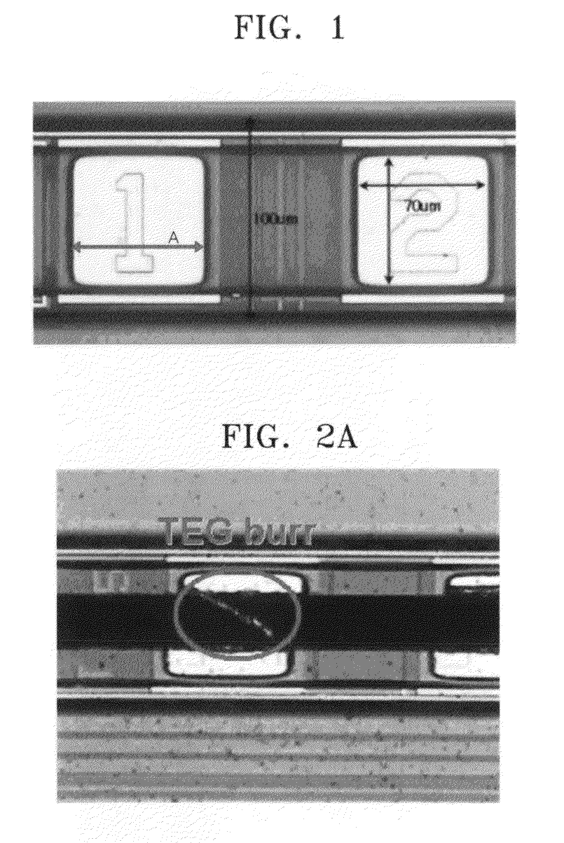

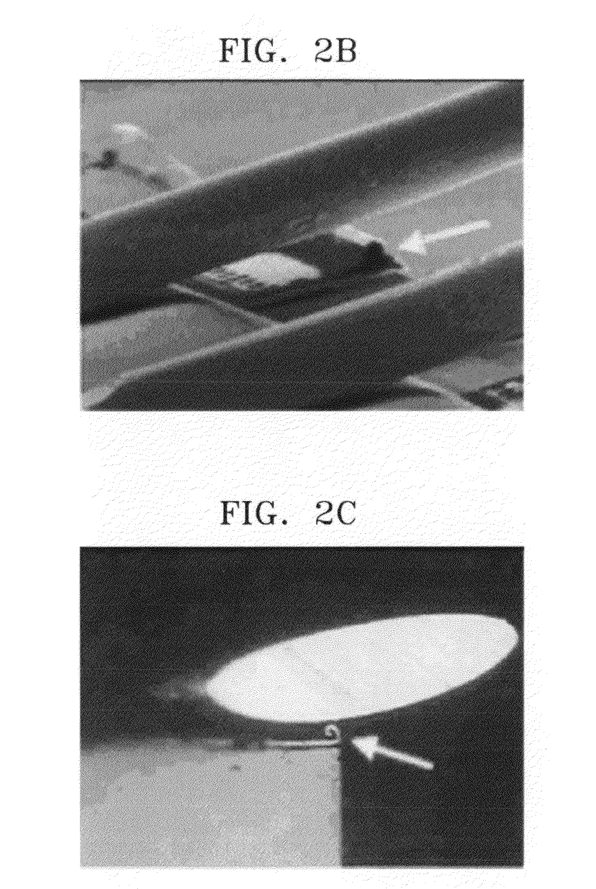

Also, as shown by comparing a length A of FIG. 1 and the overlapping length B of FIG. 4, a length for which a burr may be formed and/or peeling may occur is shorter in example embodiments, and thus the formation of the burr and/or the occurrence of peeling may be further reduced.

At least one other example embodiment provides a method of fabricating a semiconductor device. The method may include forming unitary semiconductor chip regions on a semiconductor substrate, forming scribe lane regions between the unitary semiconductor chip regions, forming test elements on the scribe lane regions, and forming TEG pads that apply a testing signal for testing the test elements, respectively. An acute angle formed at an intersection of an extended line of at least a portion of the perimeter of the TEG pads and at least a portion of the outer edge of the scribe lanes or scribe lane regions may be greater than 0° and less than or equal to 60°.

The formation of the unitary semiconductor chip regions, the formation of the scribe lane regions between the semiconductor chip regions, and the formation of the test element on the scribe lane regions may be performed using a method well known to one skilled in the art.

The formation of the TEG pads in accordance with example embodiments (e.g., such that an acute angle formed at an intersection at which the perimeter of the TEG pads and a cutting line formed by dicing the semiconductor substrate along a direction in which the scribe lane region extends cross is greater than 0° and less than or equal to 60°) may be done by forming a TEG pad layer on the semiconductor substrate using a method such as a deposition and using a lithographic mask as an etching mask to etch the TEG pad layer. The lithographic mask may be designed such that the perimeter of the TEG pad is capable of crossing the cutting line in an angle greater than 0° and less than or equal to 60°.

Besides the formation of the TEG pads described above, the same or substantially the same principle may be applied to this example embodiment. Therefore, a description of common principle is omitted to avoid repetition.

At least one other example embodiment provides an electronic device having a unitary semiconductor chip formed on a semiconductor wafer as described with regard to the example embodiments shown in FIGS. 3-5. Examples of the electronic devices may include a memory device such as a dynamic random access memory (DRAM) or a flash memory, an audio device such as a MP3 player, a display device such as a television, a portable multimedia player (PMP), a communication device such as a cellular phone, etc.; however, the electronic device is not limited thereto.

A unitary semiconductor chip formed on the semiconductor wafer according to example embodiments and then employed on an independent electronic device may have a slight mark due to the TEG pad nearby the edges of the unitary semiconductor chip. As a result, semiconductor chips according to example embodiments may be identified by confirming whether the perimeter of the TEG pad crosses the cutting line, for example, the edge of the unitary semiconductor chip at the aforementioned angle or not.

While the present invention has been particularly shown and described with reference to example embodiments thereof, it will be understood by one of ordinary skill in the art that various changes in form and details may be made therein without departing from the spirit and scope of the present invention as defined by the following claims.

1. A semiconductor wafer comprising:
a plurality of unitary semiconductor chips formed on a semiconductor substrate;
scribe lane regions separating the plurality of unitary semiconductor chips from each other; and
test element group (TEG) pads arranged within the scribe lane regions, the TEG pads being configured to apply testing signals for testing respective test elements, at least a first of the TEG pads being arranged such that an acute angle formed at an intersection of a line extending from portion of a perimeter of the first TEG pad and at least a portion of the outer edge of a corresponding scribe lane region is greater than 0° and less than or equal to 60°.

2. The semiconductor wafer of claim 1, wherein the acute angle is between 10° and 50°, inclusive.

3. The semiconductor wafer of claim 1, wherein an acute angle formed at an intersection of at least a portion of the perimeter of the first TEG pad and a cutting line to be formed by dicing the semiconductor wafer along a direction in which the corresponding scribe lane region extends is greater than 0° and less than or equal to 60°.

4. The semiconductor wafer of claim 3, wherein the first TEG pad overlaps a portion of the cutting line, the length of the overlapped portion of the cutting line being smaller than 40 μm.

5. The semiconductor wafer of claim 4, wherein the length of the overlapped portion of the cutting line is smaller than 25 μm.

6. The semiconductor wafer of claim 3, wherein at least the first TEG pad has a substantially rectangular shape, and an acute angle formed at an intersection of one or more of two neighboring sides of the first TEG pad and the cutting line is greater than 0° and less than or equal to 60°.

7. The semiconductor wafer of claim 6, wherein at least the first TEG pad is substantially square shaped.

8. The semiconductor wafer of claim 1, wherein at least the first TEG pad has either a circular or elliptical shape.

9. A method of fabricating a semiconductor device, the method comprising:
forming unitary semiconductor chip regions on a semiconductor substrate;
forming scribe lane regions between the unitary semiconductor chip regions; and
forming test element group (TEG) pads in the scribe lane regions, the TEG pads being configured to apply a testing signal for testing respective test elements, at least a first of the TEG pads being arranged such that an acute angle formed at an intersection of a line extending from portion of a perimeter of the first TEG pad and at least a portion of the outer edge of a corresponding scribe lane region is greater than 0° and less than or equal to 60°.

10. The method of claim 9, wherein the acute angle is between 10° and 50°, inclusive.

11. The method of claim 9, wherein an acute angle formed at an intersection of at least a portion of the perimeter of the first TEG pad and a cutting line to be formed by dicing the semiconductor wafer along a direction in which the corresponding scribe lane region extends is greater than 0° and less than or equal to 60°.

12. The method of claim 11, wherein the first TEG pad is formed to overlap a portion of the cutting line, the length of the overlapped portion of the cutting line being smaller than 40 μm.

13. The method of claim 12, wherein the length of the overlapped portion is smaller than 25 μm.

14. The method of claim 11, wherein at least the first TEG pad has a substantially rectangular shape, and an acute angle formed at an intersection of one or more of two neighboring sides of the first TEG pad and the cutting line is greater than 0° and less than or equal to 60°.

15. The method of claim 14, wherein at least the first TEG pad is substantially square shaped.

16. The method of claim 9, wherein at least the first TEG pad has either a circular or elliptical shape.

17. An electronic device comprising:
the unitary semiconductor chips formed on the semiconductor wafer of claim 1.

18. A semiconductor wafer comprising:
a plurality of unitary semiconductor chips formed on a semiconductor substrate;
scribe lane regions separating the plurality of unitary semiconductor chips from each other; and
test element group (TEG) pads arranged within the scribe lane regions, the TEG pads being configured to apply testing signals for testing respective test elements, at least a first of the TEG pads being arranged such that an acute angle formed at an intersection of at least a portion of a perimeter of the first TEG pad and a cutting line to be formed by dicing the semiconductor wafer in a direction in which a corresponding scribe lane region extends is greater than 0° and less than or equal to 60°.

19. The semiconductor wafer of claim 18, wherein at least the first TEG pad has a substantially rectangular shape, and an acute angle formed at an intersection of one or more of two neighboring sides of the first TEG pad and the cutting line is greater than 0° and less than or equal to 60°.

20. The semiconductor wafer of claim 18, wherein at least the first TEG pad has one of substantially square, circular or elliptical shape.
